(19) United States
(12) Patent Application Publication
(10) Pub. No.: US 2011/0101353 A1
(43) Pub. Date: May 5, 2011

(54) Display device and method of manufacturing the same

(76) Inventors: Jong-Hyun Park, Yongin-City (KR); Chun-Gi You, Yongin-city (KR); Sun Park, Yongin-city (KR); Jin-Hee Kang, Yongin-city (KR); Yul-Kyu Lee, Yongin-city (KR)

(21) Appl. No.: 12/805,994

(22) Filed: Aug. 27, 2010

(30) Foreign Application Priority Data
Nov. 5, 2009 (KR) 10-2009-0106628

(51) Int. Cl. H01L 33/00

(52) U.S. Cl. 257/59; 438/22; 257/E33.053; 257/E33.001

(57) ABSTRACT

A display device and a method of manufacturing the same, the display device including a substrate, a semiconductor layer on the substrate, a light shielding layer on the substrate, the light shielding layer and the semiconductor layer being positioned directly on a same layer, a gate insulating layer on the substrate covering the semiconductor layer and the light shielding layer, and a gate electrode on the gate insulating layer, the gate electrode corresponding to a channel region of the semiconductor layer.

### BACKGROUND

1. Field

Example embodiments relate to a display device and a method of manufacturing the same. More particularly, example embodiments relate to a display device that can realize images and a method of manufacturing the same.

2. Description of the Related Art

In an active matrix (AM) type that has been widely used for display devices, thin film transistors may be formed on a substrate to control pixels in order to display images. For example, an AM type organic light emitting diode (AM-OLED) display device may have a unit pixel region defined by arranged signal lines. The signal lines may include a plurality of metal interconnections, e.g., a gate signal interconnection, a data signal interconnection, a power supply voltage interconnection, etc. The metal interconnections, however, may cause reflection or interference of external light and light between adjacent pixels, resulting in a decrease in a contrast ratio (CR) of the display device.

### SUMMARY

Embodiments are therefore directed to a display device and a method of manufacturing the same, which substantially overcome one or more of the problems due to the limitations and disadvantages of the related art.

It is therefore a feature of an embodiment to provide a display device with an improved structure of a polysilicon semiconductor layer.

It is therefore another feature of an embodiment to provide a method of manufacturing a display device by preventing incomplete crystallization of an amorphous silicon layer during formation of a polysilicon semiconductor layer.

It is yet another feature of an embodiment to provide a method of manufacturing a display device by preventing contamination of a polysilicon semiconductor layer.

At least one of the above and other features and advantages may be realized by providing a display device, including a substrate, a semiconductor layer formed on the substrate, a light shielding layer formed on the same layer as the semiconductor layer, a gate insulating layer formed on the substrate including the semiconductor layer and the light shielding layer, and a gate electrode formed on the gate insulating layer to correspond to a channel region of the semiconductor layer.

The display device may further include an interlayer insulating layer on the gate insulating layer covering the gate electrode, and source and drain electrodes on the interlayer insulating layer, the source and drain electrodes being electrically connected with source and drain regions of the semiconductor layer. The display device may further include a contamination prevention layer on the semiconductor layer. The contamination prevention layer may include a single silicon oxide layer or a combination of silicon oxide and silicon nitride. A thickness ratio of the contamination prevention layer to the gate insulating layer may be in a range of about 1:3 to about 1:1.5. The gate insulating layer may be on the contamination prevention layer, and the display device may further include an interlayer insulating layer on the gate insulating layer covering the gate electrode, and source and drain electrodes on the interlayer insulating layer, the source and drain electrodes being electrically connected with source and drain regions of the semiconductor layer. The contamination prevention layer may overlap an entire upper surface of the semiconductor layer. The light shielding layer may include a metal. The metal may include one or more of aluminum, tungsten, titanium, tantalum, chromium, a chromium alloy, molybdenum, and a molybdenum alloy. The light shielding layer and the semiconductor layer may be horizontally spaced apart from each other. A portion of the gate insulating layer may be on a same layer as the light shielding layer, the portion of the gate insulating layer separating the light shielding layer and the semiconductor layer.

At least one of the above and other features and advantages may also be realized by providing a method of manufacturing a display device, including forming a semiconductor layer on a substrate, depositing a layer for forming a light shielding layer on the substrate having the semiconductor layer, etching the layer to form a light shielding layer on the same layer as the semiconductor layer at such a position that the light shielding layer is spaced apart from the semiconductor layer, forming a gate insulating layer on the substrate having the semiconductor layer and the light shielding layer, and forming a gate electrode corresponding to a channel region of the semiconductor layer on the gate insulating layer.

The method may further include forming a contamination prevention layer on the semiconductor layer, the contamination prevention layer being formed before forming the light shielding layer. The contamination prevention layer may be formed of a single silicon oxide layer or a combination of silicon oxide and silicon nitride. A thickness ratio of the contamination prevention layer to the gate insulating layer may be formed in a range of about 1:3 to about 1:1.5. The gate insulating layer may be formed on the contamination prevention layer, and the method may further include forming an interlayer insulating layer on the gate insulating layer having the gate electrode, partially exposing source and drain regions of the semiconductor layer by removing parts of the contamination prevention layer, the gate insulating layer, and the interlayer insulating layer, patterning and forming source and drain electrodes on the interlayer insulating layer, forming a planarization layer on the interlayer insulating layer including the source and drain electrodes to partially expose one of the source and drain electrodes, forming a pixel electrode on the planarization layer, forming a pixel defining layer on the planarization layer including the pixel electrode, the pixel defining layer partially exposing the pixel electrode, forming an organic layer including an organic light emitting layer on the exposed pixel electrode, and forming a counter electrode on the pixel defining layer including the organic layer.

The light shielding layer may be formed of a metal. The metal may include one or more of aluminum, tungsten, titanium, tantalum, chromium, a chromium alloy, molybdenum, and a molybdenum alloy. The method may further include forming an interlayer insulating layer on the gate insulating layer having the gate electrode, partially exposing source and drain regions of the semiconductor layer by removing parts of the gate insulating layer and the interlayer insulating layer, patterning and forming source and drain electrodes on the interlayer insulating layer, forming a planarization layer on the interlayer insulating layer including the source and drain electrodes to partially expose one of the source and drain electrodes, forming a pixel electrode on the planarization layer, forming a pixel defining layer on the planarization layer including the pixel electrode, the pixel defining layer partially exposing the pixel electrode, forming an organic layer including an organic light emitting layer on the exposed pixel electrode, and forming a counter electrode on the pixel defining layer including the organic layer. Forming the light shielding layer may include depositing a layer on the substrate, and etching the layer to form the light shielding layer on the same layer as the semiconductor layer, such that a position of the light shielding layer is horizontally spaced apart from the semiconductor layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a display device and a method of manufacturing the same according to an exemplary embodiment; and

FIG. 2 illustrates a cross-sectional view of a display device and a method of manufacturing the same according to another exemplary embodiment.

### DETAILED DESCRIPTION

Korean Patent Application No. 10-2009-0106628, filed on Nov. 5, 2009, in the Korean Intellectual Property Office, and entitled: “Display Device and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Therefore, it should be understood that the example embodiments may apply to different types of flat-panel display devices, e.g., a liquid crystal display device.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

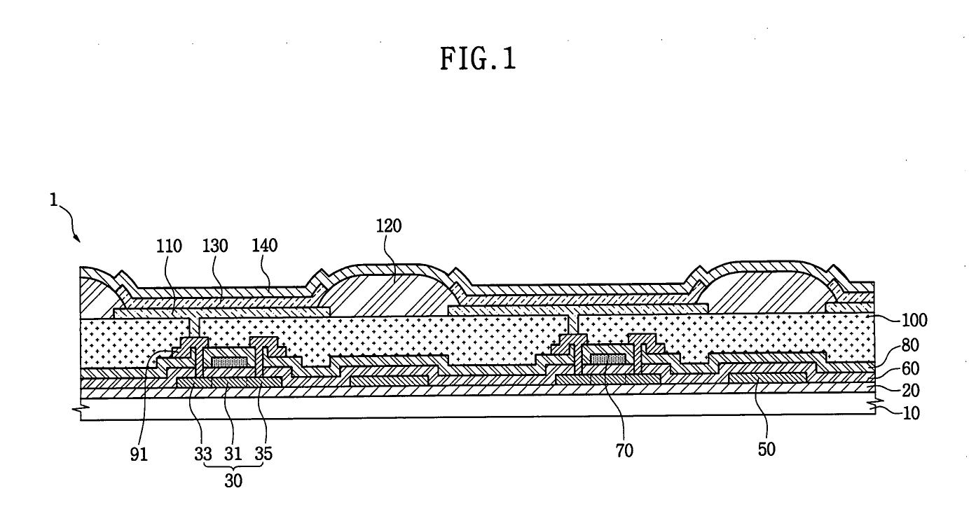

FIG. 1 illustrates a cross-sectional view of a display device and a method of manufacturing the same according to an exemplary embodiment. Referring to FIG. 1, a display device 1 according to an exemplary embodiment may include a substrate 10, a buffer layer 20 formed on the substrate 10, a semiconductor layer 30 patterned on, e.g., directly on, the buffer layer 20 and including a channel region 31 and source and drain regions 33 and 35, and a light shielding layer 50. The buffer layer 20 may be used to prevent the semiconductor layer 30 from being contaminated by the substrate 10, e.g., via diffusion, and may not be formed according to the working processes.

The semiconductor layer 30 may be formed by depositing an amorphous silicon thin layer on the buffer layer 20, crystallizing the amorphous silicon thin layer, i.e., by application of heat to the amorphous silicon thin layer, to form a polysilicon thin layer, and removing a part of the polysilicon thin layer through an etching process. Alternatively, the semiconductor layer 30 may be formed by depositing an amorphous silicon thin layer on the buffer layer 20, patterning a part of the amorphous silicon thin layer through an etching process, and subjecting the patterned amorphous silicon thin layer to a crystallization process, i.e., by applying heat to the patterned amorphous silicon thin layer.

After formation of the semiconductor layer 30, the light shielding layer 50 may be formed on, e.g., directly on, the buffer layer 20. The light shielding layer 50 may compensate for reflection or interference of the external light and/or the light between the adjacent pixels. The light shielding layer 50 may be spaced apart from the semiconductor layer 30. That is, the light shielding layer 50 may be formed on, e.g., directly on, the same layer as the semiconductor layer 30, e.g., both the semiconductor layer 30 and the light shielding layer 50 may be formed directly on the buffer layer 20, but may be horizontally spaced apart from each other. Since the light shielding layer 50 and the semiconductor layer 30 are close to each other but spaced apart from each other, the light shielding layer 50 may not overlap the semiconductor layer 30 along a vertical direction. Here, the expression “formed on the same layer” includes the meaning that one element is arranged right above the same layer as another element.

The light shielding layer 50 may be formed by depositing a layer for forming a light shielding layer 50 on the buffer layer 20 including the semiconductor layer 30, followed by removing a part of the layer through an etching process. The light shielding layer 50 may be formed of a metal, e.g., one or more of aluminum, tungsten, titanium, tantalum, chromium, a chromium alloy, molybdenum, a molybdenum alloy, and the like. It is noted, however, that the light shielding layer 50 is not limited to the above materials.

In contrast, a conventional light shielding layer may be formed under a semiconductor layer, e.g., in a bottom layer of a thin film transistor substrate, so the semiconductor layer may be formed after formation of the conventional light shielding layer, i.e., the conventional light shielding layer, insulating layer, and an amorphous silicon layer may be sequentially formed on the substrate. As such, heat applied to crystallize the amorphous silicon thin layer of the semiconductor layer may be transferred to the conventional light shielding layer, resulting in loss of thermal energy. Thus, the amorphous silicon thin layer of the semiconductor layer may be incompletely crystallized, thereby causing defects in the semiconductor layer, e.g., production of thin film transistors having poor properties. Therefore, when the semiconductor layer 30 according to exemplary embodiments is formed before the light shielding layer 50 and horizontally spaced apart therefrom, the crystallization process of the amorphous silicon thin layer of the semiconductor layer 30 may be performed before formation of the light shielding layer 50. Therefore, loss in thermal energy may be prevented or substantially minimized, thereby improving the structure, i.e., crystallization, of the semiconductor layer 30.

As further illustrated in FIG. 1, the display device 1 may include a gate insulating layer 60 on the buffer layer 20 including the semiconductor layer 30 and the light shielding layer 50. Further, a gate electrode 70 may be patterned on the gate insulating layer 60 to correspond to the channel region 31 of the semiconductor layer 30.

It is noted that when the buffer layer 20 is omitted, the semiconductor layer 30 and the light shielding layer 50 may be formed on, e.g., directly on, the substrate 10. Further, the gate insulating layer 60 may be formed on, e.g., directly on, the substrate 10 to cover the semiconductor layer 30 and the light shielding layer 50.

As illustrated in FIG. 1, the display device 1 may include an interlayer insulating layer 80 formed on the gate insulating layer 60 including the gate electrode 70. Parts of source and drain regions 33 and 35 of the semiconductor layer 30 may be exposed by partially removing the gate insulating layer 60 and the interlayer insulating layer 80. Therefore, source and drain electrodes 91 and 93 patterned on the interlayer insulating layer 80 may be electrically connected with the exposed regions of the source and drain regions 33 and 35, respectively.

A planarization layer 100 may be formed on the interlayer insulating layer 80 including the source and drain electrodes 91 and 93. A part of one of the source and drain electrodes 91 and 93 may be exposed by removing a part of the planarization layer 100.

Before formation of the planarization layer 100, a passivation layer (not shown) made of a single layer of silicon oxide (SiO₂) or silicon nitride (SiNx) or a combination thereof may be further formed on the interlayer insulating layer 80. Further, a pixel electrode 110 may be patterned on the planarization layer 100. The pixel electrode 110 may be electrically connected with the exposed part of one of the source and drain electrodes 91 and 93. The pixel electrode 110 may have a stacked structure where an indium tin oxide (ITO) or indium zinc oxide (IZO) transparent electrode is stacked on a reflective electrode, e.g., an electrode including one or more of Pt, Au, Ir, Cr, Mg, Ag, Al, and/or alloys thereof.

A pixel defining layer 120 may be formed on the planarization layer 100 including the pixel electrode 110. The pixel defining layer 120 may include an opening through which a part of the pixel electrode 110 is exposed. The pixel defining layer 120 may include one or more of benzocyclobutene (BCB), acrylic polymers, polyimide, and the like.

An organic layer 130 including an organic light emitting layer may be formed on the pixel electrode 110 exposed through the opening of the pixel defining layer 120. A counter electrode 140 may be formed on the pixel defining layer 120 including the organic layer 130.

According to example embodiments, the light shielding layer 50 may be formed after formation of the semiconductor layer 30 to be spaced apart therefrom. Therefore, the light shielding layer 50 may prevent light from being introduced into the semiconductor layer 30 by reflection, diffraction, and diffusion of the light when external light is incident or when other adjacent pixel regions emit light. Further, incomplete crystallization of the semiconductor layer 30 may be prevented or substantially minimized, thereby improving operability and reliability of the display device 1. A display device according to an exemplary embodiment may be a top emission-type display device or a bottom emission-type display device.

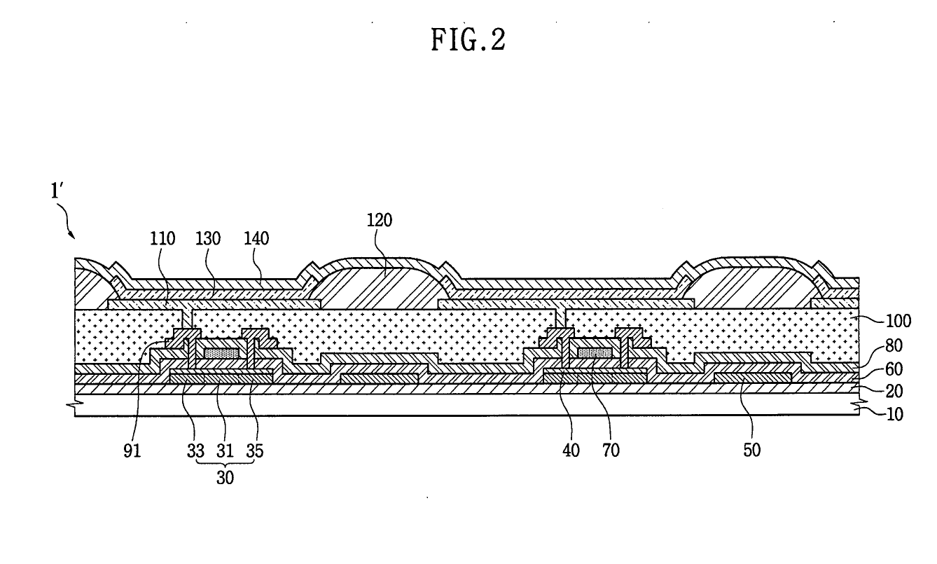

FIG. 2 illustrates a cross-sectional view of a display device and a method of manufacturing the same according to another exemplary embodiment. Referring to FIG. 2, a display device 1′ according to an exemplary embodiment may include the substrate 10, the buffer layer 20 formed on the substrate 10, and the semiconductor layer 30 patterned on the buffer layer 20 and including the channel region 31 and the source and drain regions 33 and 35. The semiconductor layer 30 may be formed by depositing an amorphous silicon thin layer on the buffer layer 20, forming a polysilicon thin layer through a crystallization process where heat is applied to the amorphous silicon thin layer, and removing a part of the polysilicon thin layer through an etching process.

As further illustrated in FIG. 2, the display device 1′ may include a contamination prevention layer 40 on the semiconductor layer 30, e.g., on an upper surface of the semiconductor layer 30 facing away from the substrate 10. The contamination prevention layer 40 may prevent the semiconductor layer 30 from being contaminated in a subsequent step of forming the light shielding layer 50. The contamination prevention layer 40 may be formed of a single layer of silicon oxide (SiO₂) or a combination of silicon oxide (SiO₂) and silicon nitride (SiNₓ).

After formation of the contamination prevention layer 40, the light shielding layer 50 may be formed to be spaced apart from the semiconductor layer 30. The light shielding layer 50 may be formed on, e.g., directly on, the same layer as the semiconductor layer 30, so that the semiconductor layer 30 and the light shielding layer 50 may be arranged close to each other and be spaced apart from each other. The light shielding layer 50 may not overlap the semiconductor layer 30 in the vertical direction. The light shielding layer 50 may be formed by depositing a layer for forming a light shielding layer 50 on the buffer layer 20 including the contamination prevention layer 40, followed by removing a part of the layer through an etching process.

Formation of the contamination prevention layer 40 on the semiconductor layer 30 prior to formation of the light shielding layer 50 according to exemplary embodiments may prevent or substantially minimize contamination of the semiconductor layer 30 during formation of the light shielding layer 50.

As further illustrated in FIG. 2, the gate insulating layer 60 may be formed on the buffer layer 20 including the contamination prevention layer 40 and the light shielding layer 50. The gate electrode 70 may be patterned on the gate insulating layer 60 to correspond to the channel region 31.

The contamination prevention layer 40 may be formed to a thickness of about 260 Å to about 400 Å. The gate insulating layer 60 may be formed to a thickness of about 620 Å to about 780 Å. That is, a thickness ratio of the contamination prevention layer 40 to the gate insulating layer 60 may be adjusted to a range of about 1:1.5 to about 1:3.

When the thickness ratio of the contamination prevention layer 40 to the insulating layer 60 exceeds about 1:3, the contamination prevention layer 40 may be relatively thin. As such, the contamination prevention layer 40 may not effectively prevent contamination of the semiconductor layer 30. Also, when the thickness ratio of the contamination prevention layer 40 to the insulating layer 60 is less than about 1:1.5, the contamination prevention layer 40 may be relatively thick, and therefore, sensitivity of an electrical reaction between the gate electrode 70 and the channel region 31 may decrease.

An interlayer insulating layer 80 may be formed on the gate insulating layer 60 including the gate electrode 70. The source and drain regions 33 and 35 may be partially exposed by removing parts of the contamination prevention layer 40, the gate insulating layer 60, and the interlayer insulating layer 80.

The source and drain electrodes 91 and 93 may be patterned on the interlayer insulating layer 80, and the planarization layer 100 may be formed on the interlayer insulating layer 80 including the source and drain electrodes 91 and 93. One of the source and drain electrodes 91 and 93 may be partially exposed by removing a part of the planarization layer 100.

The pixel electrode 110 may be patterned on the planarization layer 100. The pixel electrode 110 may be electrically connected with the exposed part of one of the source and drain electrodes 91 and 93, and the pixel defining layer 120 may be formed on the planarization layer 100 including the pixel electrode 110. The pixel defining layer 120 may include an opening through which a part of the pixel electrode 110 is exposed.

The organic layer 130 including an organic light emitting layer may be formed on the pixel electrode 110 exposed through the opening of the pixel defining layer 120. The counter electrode 140 may be formed on the pixel defining layer 120 including the organic layer 130.

According to exemplary embodiments, it may be possible to prevent thermal energy, required to crystallize the amorphous silicon layer, from being transferred to a light shielding layer. Accordingly, a display device according to exemplary embodiments may include a homogenous polysilicon layer, i.e., incomplete crystallization of an amorphous silicon layer may be prevented or substantially minimized, thereby reducing production of thin film transistors having poor properties. Also, the display device according to exemplary embodiments may include a contamination prevention layer on the semiconductor layer capable of preventing contamination of the semiconductor layer during formation of the light shielding layer.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A display device, comprising:
a substrate;
a semiconductor layer on the substrate;
a light shielding layer on the substrate, the light shielding layer and the semiconductor layer being positioned directly on a same layer;
a gate insulating layer on the substrate covering the semiconductor layer and the light shielding layer; and
a gate electrode on the gate insulating layer, the gate electrode corresponding to a channel region of the semiconductor layer.

2. The display device as claimed in claim 1, further comprising:
an interlayer insulating layer on the gate insulating layer covering the gate electrode; and
source and drain electrodes on the interlayer insulating layer, the source and drain electrodes being electrically connected with source and drain regions of the semiconductor layer.

3. The display device as claimed in claim 1, further comprising a contamination prevention layer on the semiconductor layer.

4. The display device as claimed in claim 3, wherein the contamination prevention layer includes a single silicon oxide layer or a combination of silicon oxide and silicon nitride.

5. The display device as claimed in claim 3, wherein a thickness ratio of the contamination prevention layer to the gate insulating layer is in a range of about 1:3 to about 1:1.5.

6. The display device as claimed in claim 3, wherein the gate insulating layer is on the contamination prevention layer, and the display device further comprises:
an interlayer insulating layer on the gate insulating layer covering the gate electrode; and
source and drain electrodes on the interlayer insulating layer, the source and drain electrodes being electrically connected with source and drain regions of the semiconductor layer.

7. The display device as claimed in claim 3, wherein the contamination prevention layer overlaps an entire upper surface of the semiconductor layer.

8. The display device as claimed in claim 1, wherein the light shielding layer includes a metal.

9. The display device as claimed in claim 8, wherein the metal includes one or more of aluminum, tungsten, titanium, tantalum, chromium, a chromium alloy, molybdenum, and a molybdenum alloy.

10. The display device as claimed in claim 1, wherein the light shielding layer and the semiconductor layer are horizontally spaced apart from each other.

11. The display device as claimed in claim 1, wherein a portion of the gate insulating layer is on a same layer as the light shielding layer, the portion of the gate insulating layer separating the light shielding layer and the semiconductor layer.

12. A method of manufacturing a display device, comprising:
forming a semiconductor layer on a substrate;
forming a light shielding layer on the substrate, the light shielding layer being formed after formation of the semiconductor layer and on a same layer as the semiconductor layer;
forming a gate insulating layer on the substrate, the gate insulating layer covering the semiconductor layer and the light shielding layer; and
forming a gate electrode on the gate insulating layer, the gate electrode corresponding to a channel region of the semiconductor layer.

13. The method as claimed in claim 12, further comprising forming a contamination prevention layer on the semiconductor layer, the contamination prevention layer being formed before forming the light shielding layer.

14. The method as claimed in claim 13, wherein the contamination prevention layer is formed of a single silicon oxide layer or a combination of silicon oxide and silicon nitride.

15. The method as claimed in claim 14, wherein a thickness ratio of the contamination prevention layer to the gate insulating layer is formed in a range of about 1:3 to about 1:1.5.

16. The method as claimed in claim 13, wherein the gate insulating layer is formed on the contamination prevention layer, and the method further comprises:
forming an interlayer insulating layer on the gate insulating layer having the gate electrode;
partially exposing source and drain regions of the semiconductor layer by removing parts of the contamination prevention layer, the gate insulating layer, and the interlayer insulating layer;
patterning and forming source and drain electrodes on the interlayer insulating layer;
forming a planarization layer on the interlayer insulating layer including the source and drain electrodes to partially expose one of the source and drain electrodes;
forming a pixel electrode on the planarization layer;
forming a pixel defining layer on the planarization layer including the pixel electrode, the pixel defining layer partially exposing the pixel electrode;
forming an organic layer including an organic light emitting layer on the exposed pixel electrode; and
forming a counter electrode on the pixel defining layer including the organic layer.

17. The method as claimed in claim 12, wherein the light shielding layer is formed of a metal.

18. The method as claimed in claim 17, wherein the metal includes one or more of aluminum, tungsten, titanium, tantalum, chromium, a chromium alloy, molybdenum, and a molybdenum alloy.

19. The method as claimed in claim 12, further comprising:
forming an interlayer insulating layer on the gate insulating layer having the gate electrode;
partially exposing source and drain regions of the semiconductor layer by removing parts of the gate insulating layer and the interlayer insulating layer;
patterning and forming source and drain electrodes on the interlayer insulating layer;
forming a planarization layer on the interlayer insulating layer including the source and drain electrodes to partially expose one of the source and drain electrodes;
forming a pixel electrode on the planarization layer;
forming a pixel defining layer on the planarization layer including the pixel electrode, the pixel defining layer partially exposing the pixel electrode;
forming an organic layer including an organic light emitting layer on the exposed pixel electrode; and
forming a counter electrode on the pixel defining layer including the organic layer.

20. The method as claimed in claim 12, wherein forming the light shielding layer includes:
depositing a layer on the substrate; and
etching the layer to form the light shielding layer on the same layer as the semiconductor layer, such that a position of the light shielding layer is horizontally spaced apart from the semiconductor layer.
